(19) United States
(12) Patent Application Publication
(10) Pub. No.: US 2011/0316150 A1
(43) Pub. Date: Dec. 29, 2011

(54) SEMICONDUCTOR PACKAGE AND METHOD FOR MANUFACTURING SEMICONDUCTOR PACKAGE

(75) Inventor: Takashi OZAWA, Nagano-shi (JP)

(73) Assignee: Shinko Electric Industries Co., Ltd., Nagano-shi (JP)

(21) Appl. No.: 13/168,039

(22) Filed: Jun. 24, 2011

(30) Foreign Application Priority Data
Jun. 25, 2010 (JP) 2010-144754

(51) Int. Cl. H01L 23/498; H01L 21/50

(52) U.S. Cl. 257/737; 438/108; 257/778; 257/E23.068; 257/E21.499

(57) ABSTRACT

A semiconductor package includes a first board, a semiconductor chip having a first face and a second face at an opposite side to the first face, the semiconductor chip being mounted on the first board with the first face facing the first board, an insulating film provided on the second face of the semiconductor chip, and a second board stacked on the first board. A bump provided on a face of the second board facing the first board is connected to a pad provided on a face of the first board facing the second board and a gap is formed between the first board and the second board. The semiconductor chip and the insulating film are provided in the gap.

### CROSS REFERENCE TO RELATED APPLICATION(S)

This application is based upon and claims the benefit of priority from Japanese Patent Application No. 2010-144754 filed on Jun. 25, 2010, the entire contents of which are incorporated herein by reference.

### TECHNICAL FIELD

The present disclosure relates to a semiconductor package and a method for manufacturing the same, which are effectively applied to a semiconductor package having a PoP (Package on Package) structure.

### RELATED ART

As an art of a semiconductor package for rendering an electronic appliance such as a mobile phone multifunctional, there has been a so-called PoP structure in which a plurality of semiconductor packages are stacked.

In Japanese Patent Publication No. JP-A-2009-146969 (Patent Document 1), there is disclosed a semiconductor package having the PoP structure (hereinafter simply referred to as “a PoP package”) which includes a semiconductor package at a lower side (a mounted side) (hereinafter simply referred to as “a lower package”) and a semiconductor package at an upper side (a mounting side) (hereinafter simply referred to as “an upper package”). In this PoP package in Patent Document 1, a semiconductor chip which is flip-chip mounted on a board of the lower package is provided between a board of the upper package and the board of the lower package.

Moreover, an art related to the flip-chip mounting is disclosed in Japanese Patent Publication No. JP-A-2003-273259 (Patent Document 2).

### [Prior Art Document]

### [Patent Document]

[Patent Document 1]

Japanese Patent Publication No. JP-A-2009-146969

[Patent Document 2]

Japanese Patent Publication No. JP-A-2003-273259

In mounting the semiconductor package having the PoP structure on the electronic appliance, it has required for the semiconductor package to be compact and thin. For this reason, in the PoP package as described in Patent Document 1, each of the lower package and the upper package must be made compact and thin. The lower package is, for example, such that the semiconductor chip is flip-chip mounted on the board. On the other hand, the upper package is, for example, such that the semiconductor chip is mounted by wire bonding on the board of the upper package, and the semiconductor chip and a bonding wire are encapsulated with mold resin.

By the way, the board to be used in the lower package and the upper package is a wiring board which includes, for example, a glass fiber containing epoxy resin, a wiring pattern, etc., and a thermal expansion coefficient of the wiring board is about 14 to 15 ppm/K. The semiconductor chip is formed of, for example, silicon, and its thermal expansion coefficient is about 3 ppm/K.

The wiring board which includes, for example, the glass fiber containing epoxy resin, the wiring pattern, etc. has a higher thermal expansion coefficient than the semiconductor chip, and remarkably expands and shrinks with heat. Therefore, when the semiconductor chip is subjected to heat treatment, for example, on occasion of mounting it, a thermal stress occurs due to a difference in the thermal expansion coefficient between the semiconductor chip and the board. As the results, warpage may occur in the board, in some cases. For example, as shown in FIG. 16, in a board 72 on which a semiconductor chip 71 is mounted, it inevitably happens that the board 72 is warped so as to swell upward.

In the PoP package employing the lower package in which such warpage has occurred, it is considered that reliability of the PoP package is deteriorated. Moreover, it is also considered that the PoP package in which the warpage remains is difficult to be treated in a production process, and a production yield of the PoP package is decreased.

Specifically, in the lower package, warpage may occur, in some cases, due to thermal stress during heat treatment (at about 150 to 200° C., for example) for hardening an under fill resin which is filled into a part (a bonding part) between the board and the semiconductor chip which is flip-chip mounted on the board. The under fill resin which is provided between the board and the chip is used for decreasing the thermal stress which occurs between the semiconductor chip and the board. However, in case where a thickness of the board of the lower package is reduced to comply with the request for making the PoP package thin, the board is warped, even though such under fill resin is used.

Moreover, warpage may occur in the lower package, in some cases, due to a thermal stress on occasion of reflow heating treatment (for example, at about 250 to 270° C.), when the lower package and the upper package are stacked, and an external connection pad of the lower package is electrically connected to an external connection bump of the upper package. Occurrence of warpage is prevented in the upper package, because the semiconductor chip on the board of the upper package is encapsulated with the mold resin.

For the purpose of preventing occurrence of the warpage of the lower package, it is considered to increase a thickness of the semiconductor chip on the lower package. However, this incurs an increase of cost for the semiconductor chip (silicon), and naturally, production cost for the PoP package is increased.

For the purpose of preventing occurrence of the warpage in the lower package, it is also considered to encapsulate the semiconductor chip on the lower package with mold resin. In case of encapsulating the semiconductor chip with the mold resin in this manner, it is necessary to enlarge a gap between the lower package and the upper package according to a thickness of the increased mold resin. Consequently, a thickness of the PoP package is increased, which is contrary to the request for making the PoP package thin. Moreover, an area corresponding to the mold resin must be secured around the semiconductor chip on the lower package, and accordingly, an area as the PoP package is increased. This is contrary to the request for making the PoP package compact.

Usually, the lower package is formed by dividing a large size board into unit pieces, for example. However, in case of encapsulating the semiconductor chip with the mold resin, the number of the unit pieces to be obtained from the large size board is decreased in order to secure the thickness of the lower package. Further, in case of encapsulating the semiconductor chip with the mold resin, cost for molding dies is high, and the production cost is inevitably increased.

### SUMMARY

Exemplary embodiments of the invention provide a semiconductor package and a manufacturing for the same which can improve the reliability of the semiconductor package.

A semiconductor package according to an exemplary embodiment includes:
a first board;
a semiconductor chip having a first face and a second face at an opposite side to the first face, the semiconductor chip being mounted on the first board with the first face facing the first board;
an insulating film provided on the second face of the semiconductor chip; and
a second board stacked on the first board,
wherein a bump provided on a face of the second board facing the first board is connected to a pad provided on a face of the first board facing the second board and a gap is formed between the first board and the second board, and
the semiconductor chip and the insulating film are provided in the gap.

A method for manufacturing a semiconductor package according to an exemplary embodiment includes:
(a) preparing a first board with a pad,
(b) preparing a second board with a bump; and
(c) stacking the second board on the first board, and connecting the bump to the pad by reflow treatment,
wherein the (a) preparing the first board includes
(a1) mounting the semiconductor chip which has a first face and a second face at an opposite side to the first face, on the first board with the first face facing the first board, and
(a2) providing an insulating film on the second face of the semiconductor chip.

Patent Document 2 discloses that in the flip-chip mounting structure, a plate member is pasted to a back face of a semiconductor chip; however, it does not disclose the PoP structure and its problem to be solved as mentioned above. In the PoP structure, insulation between a lower package and an upper package must be secured except connection parts. However, Patent Document 2 uses aluminum or copper, for example, as a main component of the plate member (See [0006] of Patent Document 2), and thus, never consider the PoP structure.

According to exemplary embodiments of the invention, it is possible to provide a semiconductor package and a manufacturing for the same which can improve the reliability of the semiconductor package.

### BRIEF DESCRIPTION OF THE DRAWINGS

FIG. 1 shows a sectional view of a PoP package in a first embodiment.

FIG. 2 shows a sectional view of a process in the manufacturing method of the PoP package shown in FIG. 1.

FIG. 3 shows a sectional view of a process subsequent to the process shown in FIG. 2 in the manufacturing method of the PoP package.

FIG. 4 shows a sectional view of a process subsequent to the process shown in FIG. 3 in the manufacturing method of the PoP package.

FIG. 5 shows a sectional view of a process subsequent to the process shown in FIG. 4 in the manufacturing method of the PoP package.

FIG. 6 shows a sectional view of a process subsequent to the process shown in FIG. 5 in the manufacturing method of the PoP package.

FIG. 7 shows a sectional view of a process subsequent to the process shown in FIG. 6 in the manufacturing method of the PoP package.

FIG. 8 shows a sectional view of a PoP package in a second embodiment.

FIG. 9 shows a sectional view of a process in the manufacturing method of the PoP package shown in FIG. 8.

FIG. 10 shows a sectional view of a process subsequent to the process shown in FIG. 9 in the manufacturing method of the PoP package.

FIG. 11 shows a sectional view of a process subsequent to the process shown in FIG. 10 in the manufacturing method of the PoP package.

FIG. 12 shows a sectional view of a process subsequent to the process shown in FIG. 11 in the manufacturing method of the PoP package.

FIG. 13 shows a sectional view of a process subsequent to the process shown in FIG. 12 in the manufacturing method of the PoP package.

FIG. 14 shows a sectional view of a PoP package in a third embodiment.

FIG. 15 shows a plan view of an essential part of the PoP package shown in FIG. 14.

FIG. 16 shows a view explaining warpage occurred in a board on which a semiconductor chip is mounted.

### DETAILED DESCRIPTION

Now, embodiments of the invention will be described in detail, referring to the drawings. It is to be noted that in all the drawings for describing the embodiments, members having the same function are denoted with the same reference numerals, and repetitive descriptions of the members will be omitted, in some cases.

### Embodiment 1

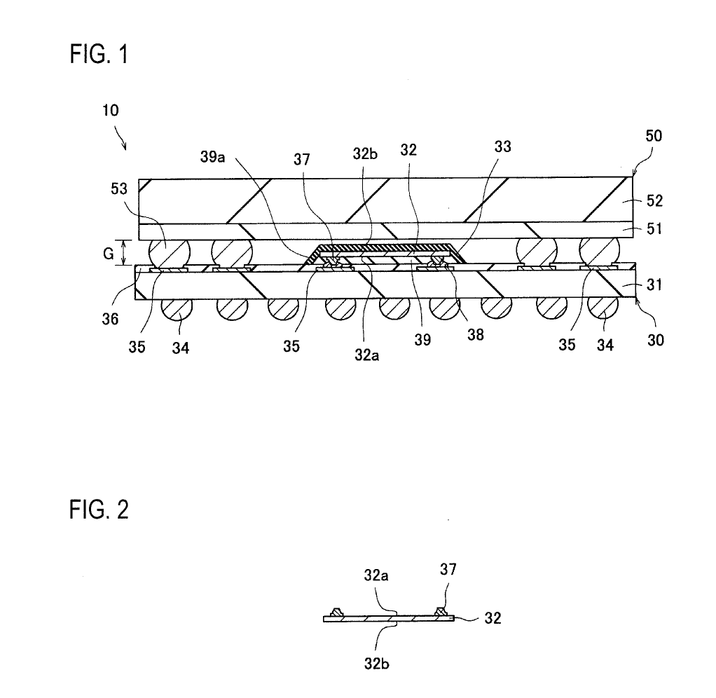

At the beginning, structure of a PoP package 10 in this embodiment will be described. FIG. 1 shows a sectional view of the PoP package 10 in this embodiment. The PoP package 10 includes a semiconductor package at a lower side (a mounted side) (hereinafter simply referred to as “a lower package”) 30 and a semiconductor package at an upper side (a mounting side) (hereinafter simply referred to as “an upper package”) 50.

The upper package 50 includes a board 51, semiconductor chips (not shown) which are mounted on a chip mounting face of the board 51, a mold resin 52 which is provided on the board 51 to encapsulate the semiconductor chips, and external connection bumps 53 which are provided on a back face of the board 51 at an opposite side to the chip mounting face and electrically connected to the semiconductor chips.

The board 51 is, for example, a wiring board having a wiring pattern or the like which is not shown. A plurality of the semiconductor chips are mounted on the board 51, and hence, the upper package 50 is formed as a multi chip package (MCP). Moreover, the external connection bumps 53 are, for example, solder balls, and a gap G (a separation distance) is formed between the lower package 30 and the upper package 50 according to a height of the solder balls. The gap G is limited to a size (height) of the external connection bumps 53, and a pitch between the adjacent external connection bumps 53 is limited by the size of the external connection bumps 53.

The lower package 30 includes a board 31, a semiconductor chip 32 mounted on a chip mounting face of the board 31, and an insulating film 33 attached to a back face of the semiconductor chip 32. The semiconductor chip 32 has a rectangular shape in a plan view, for example, and has a main face (an element forming face) 32a and the back face 32b at an opposite side thereto (See FIG. 2). Moreover, the lower package 30 is provided with an under fill resin 39 which is formed between the board 31 and the semiconductor chip 32. Thermal expansion coefficient of the under fill resin 39 is about 55 to 60 ppm/K, for example.

Moreover, the lower package 30 includes external connection bumps 34 which are provided on a back face of the board 31 at an opposite side to the chip mounting face, and electrically connected to the semiconductor chip 32. It is to be noted that these external connection bumps 34 may be substituted with external connection pads.

The board 31 is, for example, a wiring board having a wiring pattern or the like which is not shown. This board 31 has external connection pads 35 which are provided at a side facing the upper package 50, and an insulating layer 36 (solder resist, for example) which is formed with openings for exposing the external connection pads 35. The semiconductor chip 32 is flip-chip mounted on the board 31. A part of the external connection pads 35 on the board 31 are electrically connected to external connection bumps 37 which are provided on the main face 32a of the semiconductor chip 32 via conductive members 38 (solder).

As described above, in the PoP package 10, the external connection bumps 53 which are provided on a face of the board 51 facing the board 31 are connected to the external connection pads 35 which are provided on a face of the board 31 facing the board 51, and the gap G is formed between the board 31 and the board 51. In this gap G, there are provided the semiconductor chip 32 which is mounted on the board 31 with the main face 32a facing the board 31, and the insulating film 33 which is attached to the back face 32b of the semiconductor chip 32.

In this manner, it is possible to prevent occurrence of warpage in the lower package 30 and in the PoP package 10 including the same, and to improve reliability of the PoP package 10. Moreover, in this embodiment, the insulating film 33 is provided so as to cover an entirety of the back face 32b of the semiconductor chip 32. However, the invention is not limited to such structure, but similar effect can be obtained, even in case where the insulating film is attached to only a center part of the back face 32b of the semiconductor chip 32.

The semiconductor chip 32 is flip-chip mounted on the board 31. The board 31 is, for example, a wiring board which includes glass fiber containing epoxy resin, a wiring pattern, etc. and its thermal expansion coefficient is about 14 to 15 ppm/K. Moreover, the semiconductor chip 32 is formed of silicon, for example, and its thermal expansion coefficient is about 3 ppm/K. In this manner, there is a difference in the thermal expansion coefficient between the board 31 and the semiconductor chip 32, and hence, the board 31 tends to be warped due to thermal stress. For this reason, in this embodiment, the insulating film 33 is attached to the back face of the semiconductor chip 32 thereby to prevent the warpage of the board 31 (the lower package 30).

For the purpose of preventing the warpage of the board 31, the thermal expansion coefficient and thickness of the insulating film 33 can be optionally selected. In case where the thermal expansion coefficient of the insulating film 33 is higher than that of the board 31, this functions so as to cancel the warpage of the board 31 due to the thermal stress, and hence, the warpage of the board 31 (the lower package 30) can be prevented. Moreover, in case where the thickness of the insulating film 33 is increased, this functions so as to cancel the warpage of the board 31 due to the thermal stress, in the same manner, and hence, the warpage of the board 31 (the lower package 30) can be prevented.

Moreover, in the PoP package 10, insulation between the lower package 30 and the upper package 50 must be secured except connection parts between the external connection pads 35 and the external connection bumps 53. Therefore, in this embodiment, the insulation performance is reliably secured, by using the insulating film 33 which is not a conductive film but an insulating film.

As described above, as the thickness of the insulating film 33 is increased more and more, the warpage of the board 31 can be prevented. However, an upper limit of the thickness of the insulating film 33 is restricted by the size of the gap G in the PoP package 10. In this embodiment, because the insulating film 33 which is an insulating film is used, the insulation performance can be secured, even though the insulating film 33 comes into contact with the board 51 of the upper package 50.

As described, in the PoP package 10, the thickness of the insulating film 33 is restricted by the size of the gap G. For this reason, it is particularly effective to use the insulating film 33 which has a higher thermal expansion coefficient than the board 31. In this embodiment, epoxy resin, for example, can be used as the insulating film 33. Thermal expansion coefficient of this epoxy resin is about 55 to 60 ppm/K. In case where the size of the gap G is, for example, about 200 μm, and the thickness of the semiconductor chip 32 is, for example, about 50 μm, the thickness of the insulating film 33 can be, for example, about 80 to 130 μm.

Moreover, by attaching the insulating film 33 to the back face of the semiconductor chip 32 so as to be in contact with the under fill resin 39, as in the PoP package 10 in this embodiment, adhesion between the insulating film 33 and the under fill resin 39 is enhanced, and thus, the warpage of the lower package 30 can be prevented. Particularly, by using the same material (epoxy resin, for example) for both the insulating film 33 and the under fill resin 39, the adhesion is further enhanced, and thus, the warpage of the lower package 30 can be prevented.

Additionally, in the PoP package 10 in this embodiment, a fillet 39a is formed on the under fill resin 39, and the insulating film 33 is attached to the back face of the semiconductor chip 32 along this fillet. As the results, the semiconductor chip 32 and the under fill resin 39 are covered with the insulating film 33. Because the semiconductor chip 32 is covered with the insulating film 33 and the under fill resin 39, the semiconductor chip 32 can be protected. Moreover, because the semiconductor chip 32 is encapsulated (covered) in the same manner as a case where the semiconductor chip 32 is encapsulated with mold resin, it is possible to prevent the warpage of the lower package 30.

Then, a method for manufacturing the PoP package 10 in this embodiment will be described. As shown in FIG. 1, the lower package 30 having the board 31 which is provided with the external connection pads 35 is prepared. Moreover, the upper package 50 having the board 51 which is provided with the external connection bumps 53 is prepared. Then, the board 51 is stacked on the board 31, and they are forwarded into a reflow furnace at about 250 to 270° C., for example, thereby to connect the external connection bumps 53 to the external connection pads 35 by reflow treatment. In this manner, the PoP package 10 is nearly completed.

This lower package 30 can be produced in the following manner. As shown in FIG. 2, in the semiconductor chip 32 having the main face (the element forming face) 32a and the back face 32b at an opposite side thereto, the external connection bumps 37 are formed on the main face 32a. These external connection bumps 37 are formed, for example, as metal bumps.

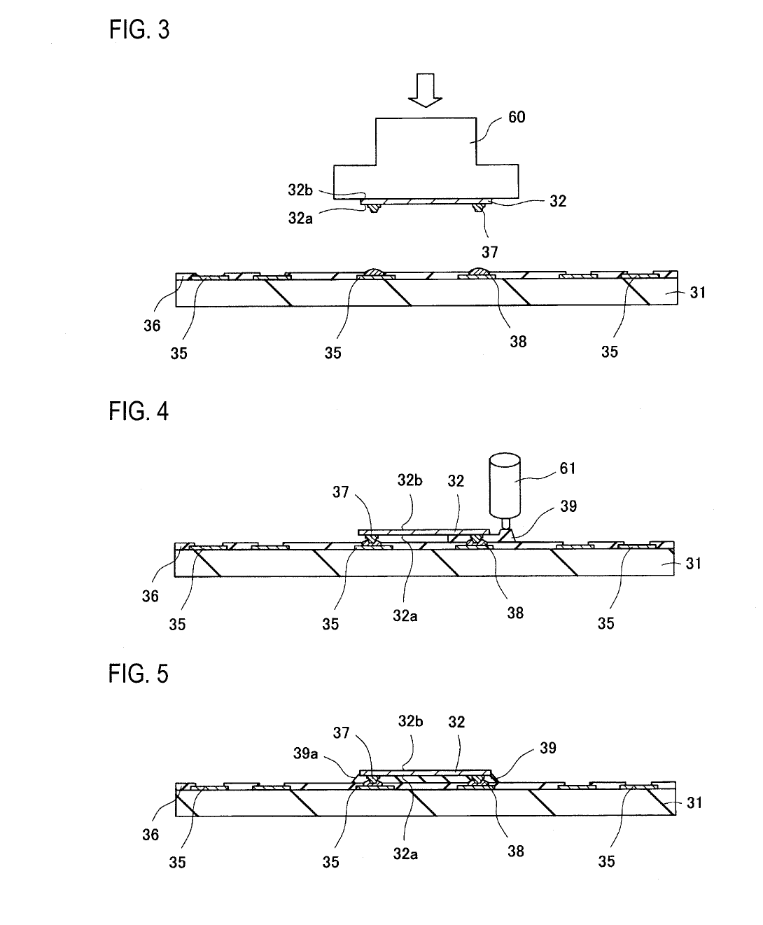

Then, as shown in FIG. 3, the semiconductor chip 32 is flip-chip mounted in a determined region (a chip mounting region) of the board 31 with the main face 32a facing the board 31. Specifically, the semiconductor chip 32 is flip-chip mounted on the board 31 by using a jig 60, while applying load and heat. As the results, as shown in FIG. 4, the external connection bumps 37 of the semiconductor chip 32 are electrically connected to the external connection pads 35 via the connecting members 38. The connecting members 38 have been formed in advance, on the external connection pads 35 of the board 31 to be electrically connected to the externally connecting bumps 37 of the semiconductor chip 32.

Then, as shown in FIG. 4, the under fill resin 39 is injected from a nozzle 61 to be filled into a space between the board 31 and the semiconductor chip 32, and the fillet 39a is formed on the under fill resin 39, as shown in FIG. 5. On this occasion, heat treatment (at about 150 to 200° C., for example) is conducted thereby to harden the under fill resin 39. On this occasion, a force for warping the board 31 with the thermal stress functions, because there is a difference in the thermal expansion coefficient between the board 31 and the semiconductor chip 32.

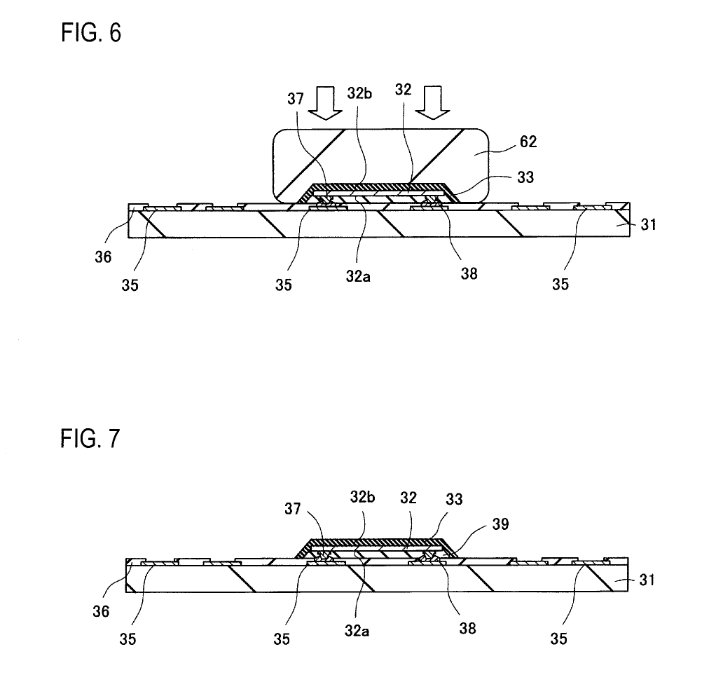

Then, the insulating film 33 is pressurized toward the back face 32b of the semiconductor chip 32, by a pressurizing part 62 having elasticity (a balloon, for example), as shown in FIG. 6, thereby to attach the insulating film 33 to the back face 32b of the semiconductor chip 32 along the fillet 39a. Because the pressurizing part 62 has elasticity, the pressure is equally applied to the insulating film 33. In this manner, the lower package 30 is nearly completed, as shown in FIG. 7.

According to this embodiment, the insulating film 33 can be attached along the fillet 39a of the under fill resin 39, and hence, adhesion between the insulating film 33, the semiconductor chip 32, and the under fill resin 39 is increased, and peeling of the insulating film 33 can be prevented. Besides, warpage of the lower package 30 and accordingly, of the PoP package 10 can be prevented, and a production yield of the PoP package 10 can be enhanced.

On occasion of the heat treatment for hardening the under fill resin 39 (treating temperature is about 150 to 200° C., for example), the force for warping the board 31 of the lower package 30 is likely to function with the thermal stress which occurs mainly due to a difference in the thermal expansion coefficient between the board 31 and the semiconductor chip 32. Moreover, on occasion of the heat treatment for connecting the lower package 30 and the upper package 50 which have been stacked, by the reflow treatment (treating temperature is about 250 to 270° C., for example), the force for warping the board 31 of the lower package 30 is likely to function with the thermal stress which occurs mainly due to a difference in the thermal expansion coefficient between the board 31 and the semiconductor chip 32.

Under the circumstances, in this embodiment, because the adhesion between the insulating film 33, the semiconductor chip 32, and the under fill resin 39 is increased, and the peeling of the insulating film 33 is prevented, a power of the insulating film 33 which functions for canceling the warpage of the board 31 can be fully exerted. Accordingly, it is possible to prevent the warpage of the PoP package 10.

### Embodiment 2

In the above described Embodiment 1, a case where the under fill resin 39 which is formed with the fillet 39a, by injecting and hardening the under fill resin in a liquid form between the board 31 of the lower package 30 and the semiconductor chip 32 is used has been described. In this embodiment, a case of using an NCF (Non Conductive Film) as the under fill resin will be described. It is to be noted that description of the other structures is omitted, in some cases, because they have been already described.

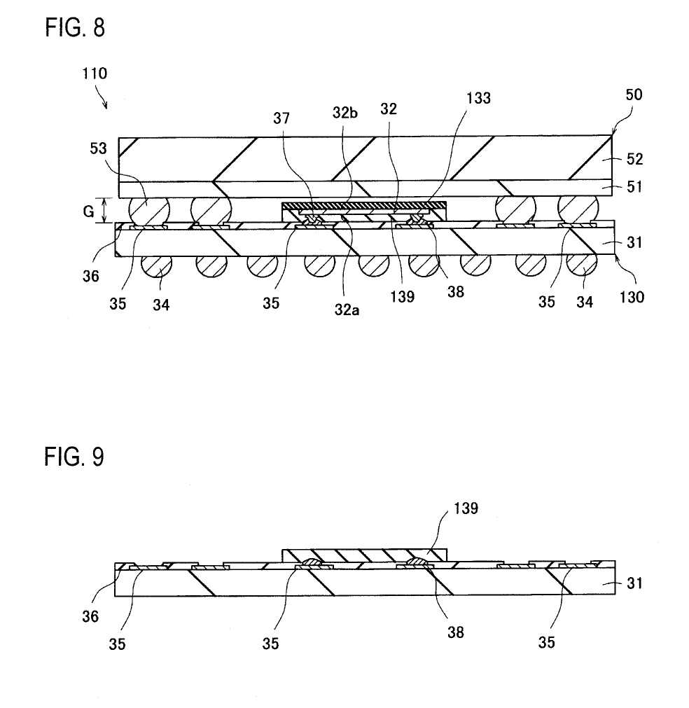

At the beginning, structure of a PoP package 110 in this embodiment will be described. FIG. 8 shows a sectional view of the PoP package 110 in this embodiment. The PoP package 110 includes a lower package 130 and the upper package 50. In the PoP package 110, the semiconductor chip 32 which is mounted on the board 31 with the main face 32a facing the board 31, and an insulating film 133 which is attached to the back face of the semiconductor chip 32 are provided in the gap G. In this manner, warpage of the lower package 130 and of the PoP package 110 including the same can be prevented, and therefore, it is possible to enhance reliability of the PoP package 110.

The semiconductor chip 32 is embedded in an under fill resin 139 formed of the NCF which is provided on the board 31, and the under fill resin 139 has a surface which is coplanar with the back face 32b of the embedded semiconductor chip 32. Moreover, the insulating film 133 is attached flatly along the surface of the under fill resin 139 and the back face 32b of the semiconductor chip 32. Because the insulating film 133 can be attached flatly, adhesion between the semiconductor chip 32 and the under fill resin 139 can be enhanced.

As the results, the semiconductor chip 32 is covered with the under fill resin 139 and the insulating film 133. Because the semiconductor chip 32 is covered with the insulating film 133, it is possible to protect the semiconductor chip 32. Moreover, because the semiconductor chip 32 is encapsulated (covered) in the same manner as the case where the semiconductor chip 32 is encapsulated with mold resin, it is possible to prevent warpage of the lower package 130.

For the purpose of preventing the warpage of the board 31, a thermal expansion coefficient and a thickness of the insulating film 133 can be optionally selected. In case where the thermal expansion coefficient of the insulating film 133 is higher than that of the board 31, this functions so as to cancel the warpage of the board 31 due to the thermal stress, and hence, the warpage of the board 31 (the lower package 130) can be prevented. Moreover, in case where the thickness of the insulating film 133 is increased, this functions so as to cancel the warpage of the board 31 due to the thermal stress in the same manner, and hence, the warpage of the board 31 (the lower package 130) can be prevented.

Moreover, in the PoP package 110, insulation between the lower package 130 and the upper package 50 must be secured except connection parts between the external connection pads 35 and the external connection bumps 53. Therefore, in this embodiment, the insulation performance is reliably secured, by using the insulating film 133 which is not a conductive film but an insulating film.

As described above, as the thickness of the insulating film 133 is increased more and more, the warpage of the board 31 can be prevented. However, an upper limit of the thickness of the insulating film 133 is restricted by the size of the gap G in the PoP package 110. In this embodiment, because the insulating film 133 which is an insulating film is used, the insulation performance can be secured, even though the insulating film 133 comes into contact with the board 51 of the upper package 50.

As described, in the PoP package 110, the thickness of the insulating film 133 is restricted by the size of the gap G. For this reason, it is particularly effective to use the insulating film 133 which has a higher thermal expansion coefficient than the board 31. In this embodiment, epoxy resin, for example, can be used as the insulating film 133. Thermal expansion coefficient of this epoxy resin is about 55 to 60 ppm/K. In case where the size of the gap G is, for example, about 200 μm, and the thickness of the semiconductor chip 32 is, for example, about 50 μm, the thickness of the insulating film 133 can be, for example, about 80 to 130 μm.

Moreover, by attaching the insulating film 133 to the back face of the semiconductor chip 32 so as to be in contact with the under fill resin 139, as in the PoP package 110 in this embodiment, adhesion between the insulating film 133 and the under fill resin 139 is enhanced, and thus, the warpage of the lower package 130 can be prevented. Particularly, by using the same material (epoxy resin, for example) for both the insulating film 133 and the under fill resin 139, the adhesion is further enhanced, and thus, the warpage of the lower package 130 can be prevented.

Then, a method for manufacturing the PoP package 110 in this embodiment will be described. As shown in FIG. 8, the lower package 130 having the board 31 which is provided with the external connection pads 35 is prepared. Moreover, the upper package 50 having the board 51 which is provided with the external connection bumps 53 is prepared. Then, the board 51 is stacked on the board 31, and they are forwarded into a reflow furnace at about 250 to 270° C., for example, thereby to connect the external connection bumps 53 to the external connection pads 35 by reflow treatment. In this manner, the PoP package 110 is nearly completed.

This lower package 130 can be produced in the following manner. As shown in FIG. 9, the under fill resin 139 is formed in a determined region (a chip mounting region) of the board 31. Specifically, the under fill resin 139 formed of the NCF is attached to the board 31.

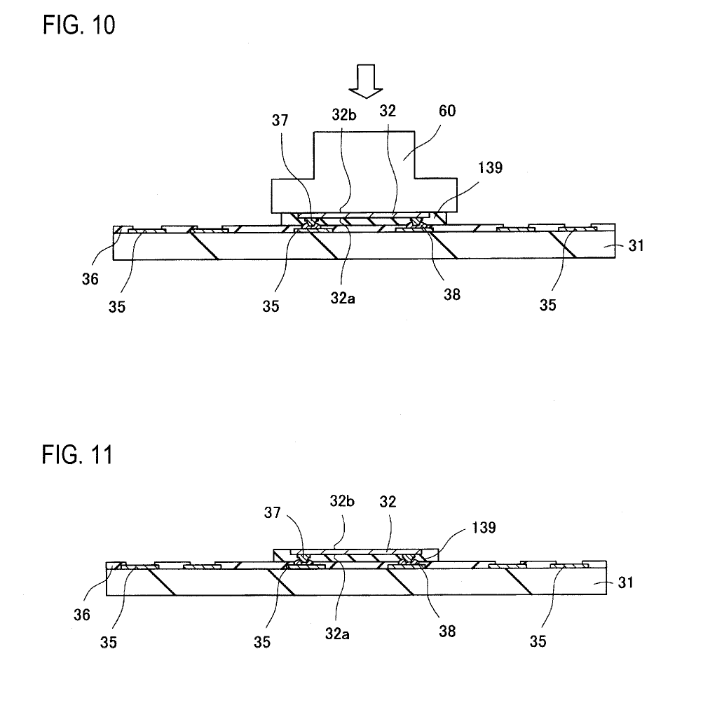

Then, as shown in FIG. 10, the semiconductor chip 32 is flip-chip mounted in the chip mounting region of the board 31 with the main face 32a facing the board 31. Specifically, the semiconductor chip 32 is flip-chip mounted on the board 31, by embedding the semiconductor chip 32 in the under fill resin 139 which is provided on the board 31 so as to form a surface coplanar with the back face 32b of the semiconductor chip 32, by using the jig 60, while applying load and heat. As the results, the external connection bumps 37 of the semiconductor chip 32 are electrically connected to the external connection pads 35 of the board 31 via the connecting members 38.

Then, heat treatment (at about 150 to 200° C., for example) is conducted thereby to harden the under fill resin 139. As the results, as shown in FIG. 11, the semiconductor chip 32 is embedded in the under fill resin 139 which is provided on the board 31, and the under fill resin 139 is formed with the surface coplanar with the back face 32b of the semiconductor chip 32 which is embedded. Because there is a difference in the thermal expansion coefficient between the board 31 and the semiconductor chip 32, a force for warping the board 31 with the thermal stress functions.

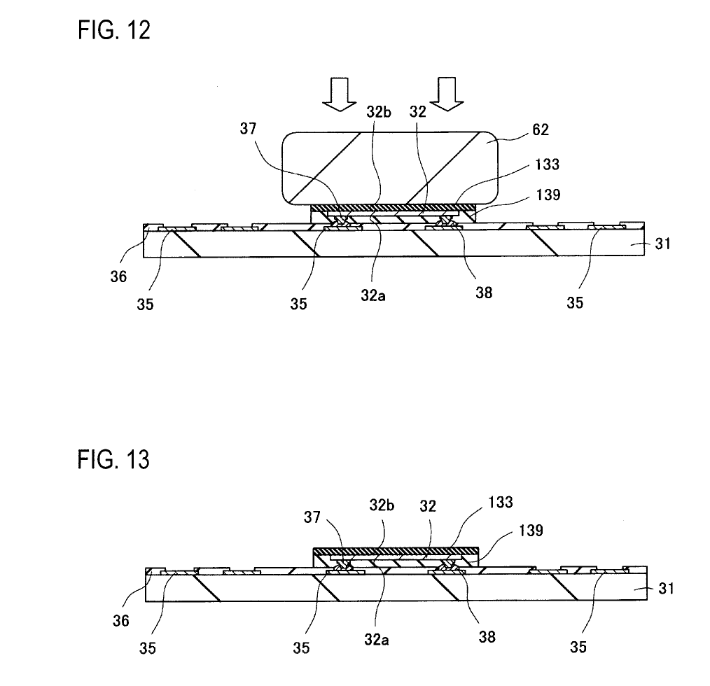

Then, the insulating film 133 is pressurized toward the back face 32b of the semiconductor chip 32, by the pressurizing part 62 having elasticity (a balloon, for example), as shown in FIG. 12, thereby to attach the insulating film 133 to the back face 32b of the semiconductor chip 32. Because the pressurizing part 62 has elasticity, the pressure is equally applied to the insulating film 133.

On this occasion, by using the insulating film 133 which is larger than the under fill resin 139 to such an extent that it can cover the under fill resin 139, it is possible to attach the insulating film 133 to the back face 32b of the semiconductor chip 32 so as to be in contact with the under fill resin 139. Moreover, the under fill resin 139 is formed with the surface coplanar with the back face 32b of the semiconductor chip 32 which is embedded in the under fill resin 139. Therefore, it is possible to attach the insulating film 133 flatly along the surface of the under fill resin 139 and the back face 32b of the semiconductor chip 32. In this manner, the lower package 130 is nearly completed, as shown in FIG. 13.

According to this embodiment, because the insulating film 133 can be attached flatly to the back face 32b of the semiconductor chip 32 and the under fill resin 139, adhesion between the insulating film 133, the semiconductor chip 32, and the under fill resin 139 is increased, and peeling of the insulating film 133 can be prevented. Besides, the warpage of the lower package 130 and the PoP package 110 can be prevented, and hence, a production yield of the PoP package 110 can be enhanced.

On occasion of the heat treatment for hardening the under fill resin 139 (treating temperature is about 150 to 200° C., for example), a force for warping the board 31 of the lower package 130 is likely to function with the thermal stress which occurs mainly due to a difference in the thermal expansion coefficient between the board 31 and the semiconductor chip 32. Moreover, on occasion of the heat treatment for connecting the lower package 130 and the upper package 50 which have been stacked, by the reflow treatment (treating temperature is about 250 to 270° C., for example), a force for warping the board 31 of the lower package 130 is likely to function with the thermal stress which occurs mainly due to a difference in the thermal expansion coefficient between the board 31 and the semiconductor chip 32.

Under the circumstances, in this embodiment, because the adhesion between the insulating film 133, the semiconductor chip 32 and the under fill resin 139 is increased, and the peeling of the insulating film 133 is prevented, a power of the insulating film 133 which functions for canceling the warpage of the board 31 can be fully exerted. Accordingly, it is possible to prevent the warpage of the PoP package 110.

### Embodiment 3

In the above described Embodiment 1, a case where the insulating film 33 is provided so as to cover the chip mounting region of the board 31 has been described. In this embodiment, a case where the insulating film is provided so as to cover an entirety of the chip mounting face of the board 31 will be described. It is to be noted that description of the other structures is omitted, in some cases, because they have been already described.

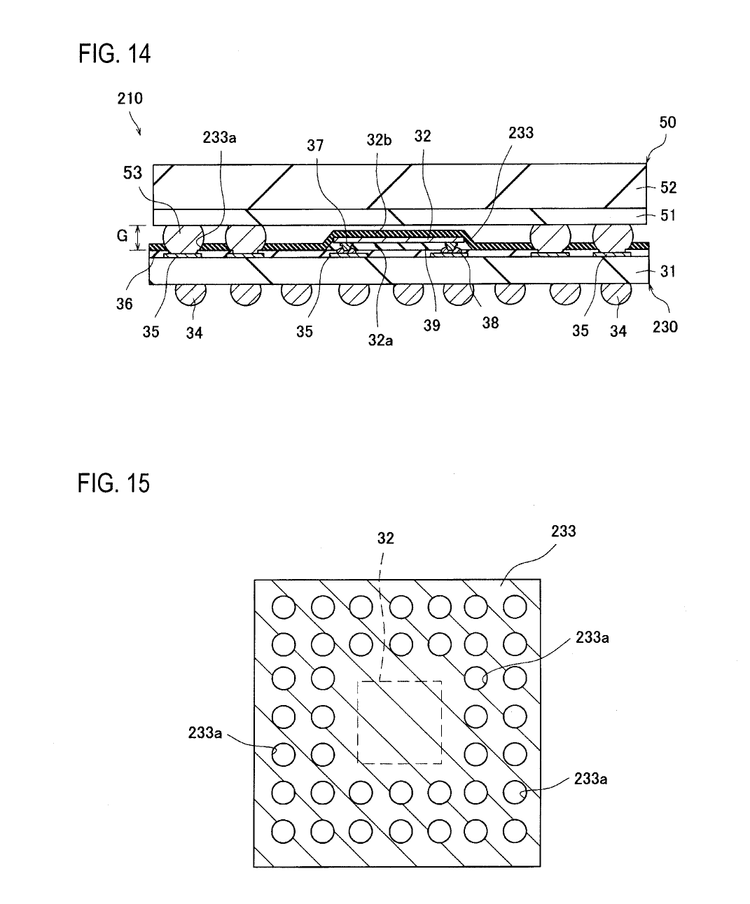

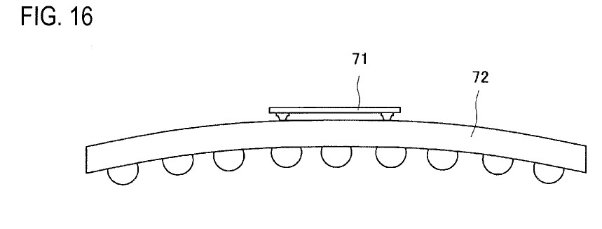

Structure of a PoP package 210 in this embodiment will be described. FIG. 14 shows a sectional view of the PoP package 210 in this embodiment. Moreover, FIG. 15 shows a plan view of an insulating film 233 which is used in the PoP package 210. It is to be noted that FIG. 15 is hatched for clarifying the description, although it is a plan view, and a region to be attached to the semiconductor chip 32 is shown by a broken line.

As shown in FIG. 14, the PoP package 210 includes a lower package 230 and the upper package 50. In the PoP package 210, there are provided in the gap G, the semiconductor chip 32 which is mounted on the board 31 with the main face 32a facing the board 31, and an insulating film 233 which is attached to the back face 32b of the semiconductor chip 32 and the entirety of the chip mounting face of the board 31 so as to cover the semiconductor chip 32.

This insulating film 233 has openings 233a for exposing the external connection pads 35 of the board 31, as shown in FIG. 15. The external connection bumps 53 of the upper package 50 are electrically connected to the external connection pads 35 of the lower package 230 in a manner passing through the openings 233a.

As described, the insulating film 233 is attached so as to cover the entirety of the chip mounting face of the board 31, besides the chip mounting region which is a part of the board 31. In this manner, warpage of the lower package 230 and of the PoP package 210 including the same can be prevented, and reliability of the PoP package 210 can be enhanced.

Moreover, in case where the external connection bumps 53 of the upper package 50 are solder balls, the solder balls are melted by conducting the reflow treatment. On this occasion, the external connection bumps 53 are electrically connected to the external connection pads 35 in such a manner that the melted solder is filled in the openings 233a of the insulating film 233. Connection parts between them are those parts to which the thermal stress is likely to be applied, in joining the upper package 50 and the lower package 230. Because the solder is filled in the openings 233a of the insulating film 233, connection strength is increased, and reliability of the PoP package 210 is enhanced.

Although the invention which has been made by the inventor has been heretofore specifically described referring to the embodiments, the invention is not limited to the above described embodiments, but various modifications can be made in a scope without deviating from gist of the invention.

In the above described embodiments, a case where the semiconductor chip is flip-chip mounted on the lower package has been described. However, the invention can be also applied to such a semiconductor package that the semiconductor chip is mounted by wire bonding. In case of the wire bonding mount, a bonding wire is drawn from an end portion of the main face of the semiconductor chip, for example. Therefore, the insulating film may be attached to an inside of the semiconductor chip.

While certain embodiments have been described, these embodiments have been presented by way of example only, and are not intended to limit the scope of the invention. Indeed, the novel package and method described herein may be embodied in a variety of other forms; furthermore, various omissions, substitutions and changes in the form of the package and method, described herein may be made without departing from the sprit of the invention. The accompanying claims and their equivalents are intended to cover such forms or modifications as would fall within the scope and sprit of the invention.

What is claimed is:

1. A semiconductor package comprising:
a first board;
a semiconductor chip having a first face and a second face at an opposite side to the first face, the semiconductor chip being mounted on the first board with the first face facing the first board;
an insulating film provided on the second face of the semiconductor chip; and
a second board stacked on the first board,
wherein a bump provided on a face of the second board facing the first board is connected to a pad provided on a face of the first board facing the second board and a gap is formed between the first board and the second board, and
the semiconductor chip and the insulating film are provided in the gap.

2. The semiconductor package as claimed in claim 1, wherein
the semiconductor chip is flip-chip mounted on the first board,
an under fill resin is provided between the first board and the semiconductor chip, and
the insulating film is provided on the second face of the semiconductor chip in a state that a part of the insulating film is in contact with the under fill resin.

3. The semiconductor package as claimed in claim 2, wherein
the under fill resin is provided with a fillet, and
the insulating film is provided on the second face of the semiconductor chip in a state that the part of the insulating film is along the fillet and in contact with the fillet.

4. The semiconductor package as claimed in claim 1, wherein
an under fill resin is provided on the face of the first board facing the second board,
the semiconductor chip is embedded in the under fill resin and is flip-chip mounted on the first board,
the under fill resin has a surface which is coplanar with the second face of the semiconductor chip, and
the insulating film is provided flatly along the surface of the under fill resin and the second face of the semiconductor chip in a state that a part of the insulating film is in contact with the surface of the under fill resin.

5. The semiconductor package as claimed in claim 1, wherein
the insulating film is provided on the second face of the semiconductor chip and on an entirety of a face of the first board on which the semiconductor chip is mounted so as to cover the semiconductor chip, and
the insulating film has an opening exposing the pad.

6. The semiconductor package as claimed in claim 1, wherein the insulating film has a higher thermal expansion coefficient than the first board.

7. A method for manufacturing a semiconductor package comprising:
(a) preparing a first board with a pad,
(b) preparing a second board with a bump; and
(c) stacking the second board on the first board, and connecting the bump to the pad by reflow treatment,
wherein the (a) preparing the first board includes
(a1) mounting the semiconductor chip which has a first face and a second face at an opposite side to the first face, on the first board with the first face facing the first board, and
(a2) providing an insulating film on the second face of the semiconductor chip.

8. The method for manufacturing a semiconductor package as claimed in claim 7, wherein
in the (a1) mounting the semiconductor chip, the semiconductor chip is flip-chip mounted on the first board,
after the (a1) mounting the semiconductor chip and before the (a2) providing the insulating film, an under fill resin is filled between the first board and the semiconductor chip, and
in the (a2) providing the insulating film, the insulating film is provided on the second face of the semiconductor chip so that a part of the insulating film is in contact with the under fill resin.

9. The method for manufacturing a semiconductor package as claimed in claim 8, wherein
the under fill resin is formed with a fillet, and
in the (a2) providing the insulating film, the insulating film is provided on the second face of the semiconductor chip so that the part of the insulating film is along the fillet and in contact with the fillet.

10. The method for manufacturing a semiconductor package as claimed in claim 7, wherein
before the (a1) mounting the semiconductor chip, an under fill resin is formed on the first board,
in the (a1) mounting the semiconductor chip, the semiconductor chip is flip-chip mounted on the first board via the under fill resin, and
in the (a2) providing the insulating film, the insulating film is provided on the second face of the semiconductor chip so that a part of the insulating film is in contact with the under fill resin.

11. The method for manufacturing a semiconductor package as claimed in claim 10, wherein
in the (a1) mounting the semiconductor chip, the semiconductor chip is flip-chip mounted on the first board, by embedding the semiconductor chip in the under fill resin provided on the first board so as to form a surface which is coplanar with the second face of the semiconductor chip, and
in the (a2) providing the insulating film, the insulating film is provided flatly along the surface of the under fill resin and the second face of the semiconductor chip so that the part of the insulating film is in contact with the surface of the under fill resin.

12. The method for manufacturing a semiconductor package as claimed in claim 7, wherein
in the (a2) providing the insulating film, the insulating film is provided on the second face of the semiconductor chip and on an entirety of a face of the first board on which the semiconductor chip is mounted so as to cover the semiconductor chip and expose the pad from an opening of the insulating film.
